(19) United States
(12) Patent Application Publication
(10) Pub. No.: US 2026/0303719 A1
(43) Pub. Date: Oct. 1, 2026

(54) ELECTRONIC DEVICE INCLUDING STRUCTURE FOR RECEIVING SOUND SIGNAL

(71) Applicant: Samsung Electronics Co., Ltd., Suwon-si (KR)

(72) Inventors: Byeonguk MIN, Suwon-si (KR); Sujin CHO, Suwon-si (KR); Hojin JUNG, Suwon-si (KR); Soyoung LEE, Suwon-si (KR); Dongjoon KIM, Suwon-si (KR)

(21) Appl. No.: 19/459,203

(22) Filed: Jan. 26, 2026

Related U.S. Application Data
(63) Continuation of application No. PCT/KR2025/020472, filed on Dec. 2, 2025.

(30) Foreign Application Priority Data
Mar. 28, 2025 (KR) 10-2025-0040723
Apr. 15, 2025 (KR) 10-2025-0049185

(51) Int. Cl. H04M 1/03; H04M 1/02; H04M 1/18; H04N 23/51; H05K 5/03; H05K 7/14

(52) U.S. Cl. CPC H04M 1/035; H04M 1/0264; H04M 1/18; H04N 23/51; H05K 5/03; H05K 7/1427; H04M 1/0216; H04M 2250/52

(57) ABSTRACT

An electronic device includes a housing. The housing includes a rear cover defining an opening and a first hole. The electronic device includes a camera. The camera is disposed in the housing such that a lens of the camera is positioned within the opening when the lens of the camera is viewed from a rear side of the housing. The electronic device includes a camera cover defining a second hole acoustically coupled to the first hole and disposed on the rear cover to cover the opening and the first hole. The camera cover includes a light transmitting portion aligned to the lens of the camera. The electronic device includes a microphone configured to receive sound waves from an outside of the electronic device passing through the second hole of the camera cover and subsequently passing through the first hole of the rear cover.

### CROSS-REFERENCE TO RELATED APPLICATIONS

This application is a continuation of an International application No. PCT/KR2025/020472, filed on Dec. 2, 2025, which is based on and claims the benefit of a Korean patent application number 10-2025-0040723, filed on Mar. 28, 2025, in the Ministry of Intellectual Property, of a Korean patent application number 10-2025-0049185, filed on Apr. 15, 2025, in the Ministry of Intellectual Property, the disclosures of each of which are incorporated by reference herein in their entireties.

### BACKGROUND

### Field

The disclosure relates to an electronic device including a structure for receiving a sound signal.

### Description of Related Art

An electronic device such as a smartphone may include one or more microphones. The one or more microphones, used for various functions such as calling, voice recording, and voice recognition, may receive an external sound through a hole or a small passage provided in the electronic device.

The above-described information may be provided as a related art for the purpose of helping understanding of the present disclosure. No assertion or determination is made as to whether any of the above description may be applied as a prior art related to the present disclosure.

### SUMMARY

According to an example embodiment, an electronic device is disclosed. The electronic device may comprise a housing. The housing may include a rear cover defining an opening and a first hole. The electronic device may comprise a camera. The camera may be disposed in the housing such that a lens of the camera is positioned within the opening when the lens of the camera is viewed from a rear side of the housing. The electronic device may comprise a camera cover defining a second hole acoustically coupled to the first hole and disposed on the rear cover to cover the opening and the first hole. The camera cover may include a light transmitting portion aligned with the lens of the camera. The electronic device may comprise a microphone configured to receive sound waves from an outside of the electronic device passing through the second hole of the camera cover and subsequently passing through the first hole of the rear cover.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram of an example electronic device in a network environment according to various embodiments.

FIG. 2A is a diagram illustrating an example of an unfolding state of an example electronic device according to various embodiments.

FIG. 2B is a diagram illustrating an example of a folding state of an example electronic device according to various embodiments.

FIG. 2C is an exploded perspective view of an example electronic device according to various embodiments.

FIG. 3A is a diagram illustrating a partial rear side of a housing of an electronic device according to various embodiments.

FIGS. 3B and 3C are partial exploded perspective views of an electronic device according to various embodiments.

FIG. 3D is a partial perspective view of an electronic device according to various embodiments.

FIG. 4 is a cross-sectional view taken along line A-A′ of FIG. 3A according to various embodiments.

FIG. 5 is a cross-sectional view taken along line B-B′ of FIG. 3A according to various embodiments.

FIG. 6 is a partial perspective view of an electronic device according to various embodiments.

### DETAILED DESCRIPTION

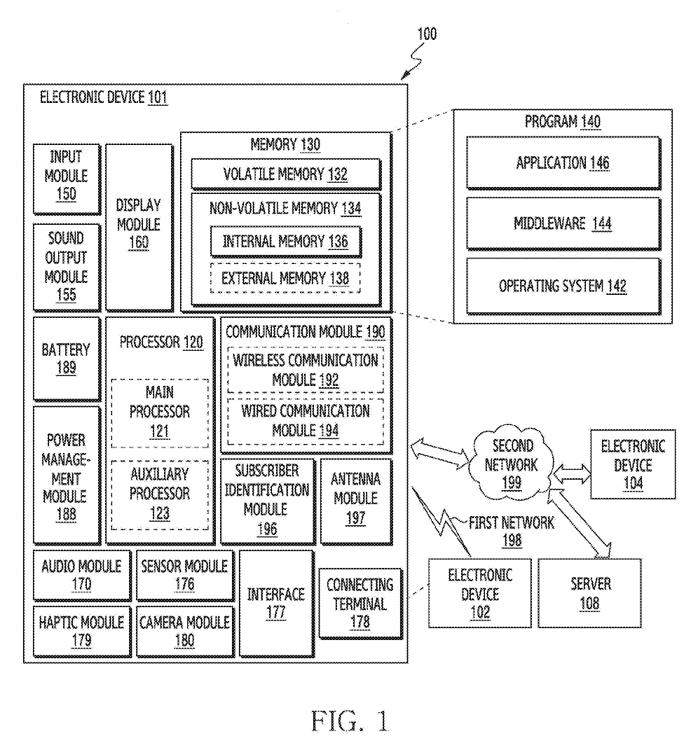

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

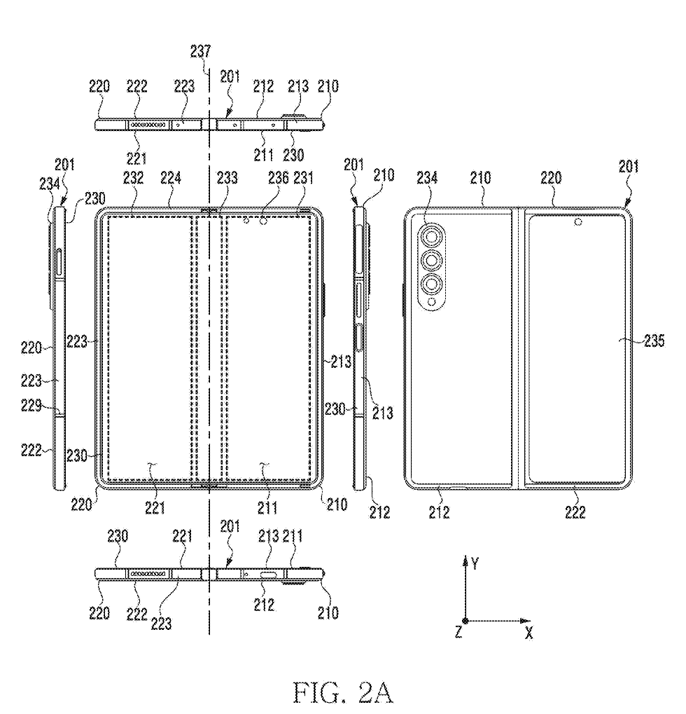

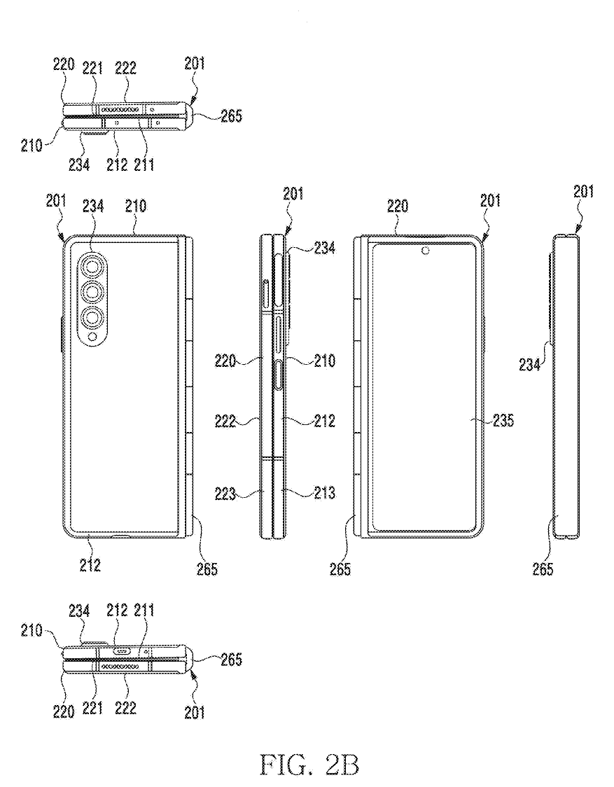

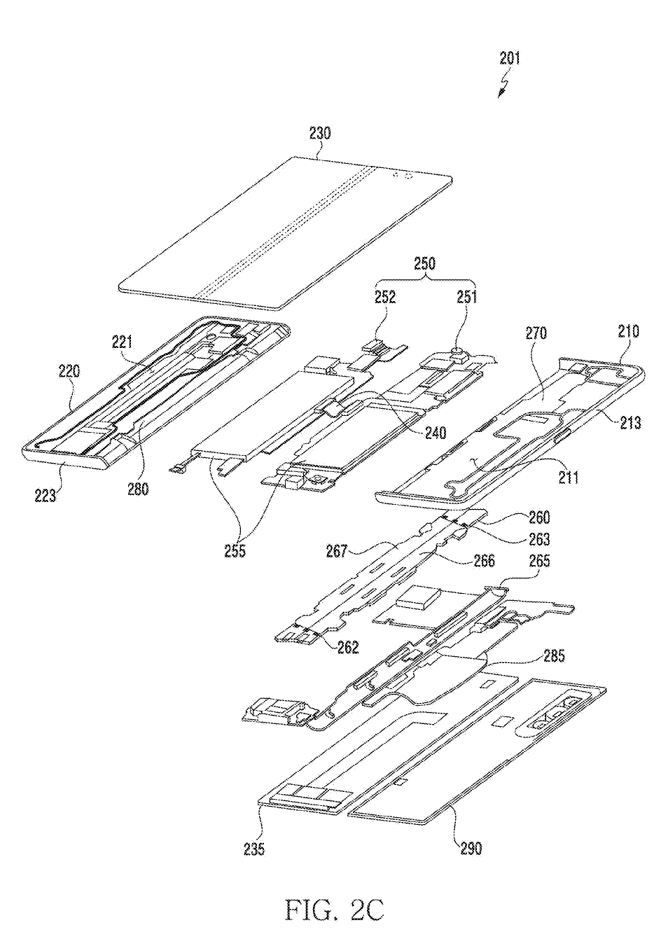

FIG. 2A is a diagram illustrating an example of an unfolding state of an example electronic device according to various embodiments, FIG. 2B is a diagram illustrating an example of a folding state of an example electronic device according to various embodiments, and FIG. 2C is an exploded perspective view of an example electronic device according to various embodiments.

Referring to FIGS. 2A, 2B, and 2C,an electronic device 201 may include a first housing part 210, a second housing part 220, and a foldable display 230. The electronic device 201 may be referred to as a foldable electronic device in that it is configured to be folded based on a folding axis 237.

In an embodiment, the electronic device 201 may include the first housing part 210, the second housing part 220, a hinge structure 260, the foldable display 230, a printed circuit board 250, a display 235, and/or a back plate 290. According to an embodiment, the electronic device 201 may omit at least one of components or may additionally include another component.

In an embodiment, the first housing part 210 may define a portion of an outer surface of the electronic device 201. For example, the first housing part 210 may define a first surface 211, a second surface 212 spaced apart from the first surface 211 and opposite to the first surface 211, and a first side surface of a first sidewall 213 surrounding at least a portion of the first surface 211 and the second surface 212. In an embodiment, the first housing part 210 may provide a space defined by the first surface 211, the second surface 212, and the first side surface as a space for disposing components of the electronic device 201.

In an embodiment, a second sidewall 223 may be rotatably (or pivotably) connected to the first sidewall 213 through a hinge structure 260 disposed on a hinge cover 265. The hinge structure 260 may include a hinge module and hinge plates 266 and 267. The hinge plates may include a first hinge plate 266 and a second hinge plate 267, the first hinge plate 266 may be connected to the first housing part 210, and the second hinge plate 267 may be connected to the second housing part 220.

In an embodiment, the second housing part 220 may include a third surface 221, a fourth surface 222 faced away from the third surface 221, and a second sidewall 223 surrounding at least a portion of the third surface 221 and the fourth surface 222. The second housing part 220 may provide a space defined by the third surface 221, the fourth surface 222, and a second side surface of the second sidewall 223 as a space for disposing components of the electronic device 201.

In an embodiment, the foldable display 230 may include a window exposed toward an outside. The window may protect a surface of the foldable display 230 and transmit visual information provided from the foldable display 230 to the outside by being formed of a transparent member. The window may include a glass material such as ultra-thin glass (UTG) or a polymer material such as polyimide (PI).

In an embodiment, the foldable display 230 may form at least a portion of the first surface 211 of the first housing part 210 (e.g., a front side of the first housing part 210) and the third surface 221 of the second housing part 220 (e.g., a front side of the second housing part 220). The foldable display 230 may be disposed on the first surface 211 of the first housing part 210 and the third surface 221 of the second housing part 220 across the hinge structure 260 in the hinge cover 265. The foldable display 230 may be configured to be bent in the folded state of the electronic device 201 by the hinge structure 260. The foldable display 230 may include a first display area 231, a second display area 232, and a third display area 233. For example, the foldable display 230 may include the first display area 231 disposed on the first surface 211 of the first housing, the second display area 232 disposed on the third surface 221 of the second housing, and the third display area 233 between the first display area 231 and the second display area 232. The foldable display 230 may be supported by a first bracket 270 of the first housing part 210 and a second bracket 280 of the second housing part 220.

According to an embodiment, the foldable display 230 may include an opening formed in a portion of a screen display area, or a bracket supporting the foldable display 230 may include a recess or an opening. The electronic device 201 may include at least one or more cameras aligned with the recess or the opening. For example, the first display area 231 may further include the at least one or more cameras 236 capable of obtaining an image from an outside through a portion of the first display area 231. According to an embodiment, the at least one or more cameras 236 may be included on a rear side of the foldable display 230 corresponding to the first display area 231 or the second display area 232 of the foldable display 230. For example, the at least one or more cameras 236 may be disposed below the foldable display 230 and may be surrounded by the foldable display 230. The at least one or more cameras 236 may be an under display camera (UDC) that is surrounded by the foldable display 230 and is not exposed to the outside. However, it is not limited thereto, and the foldable display 230 may include an opening exposing the at least one or more cameras 236 to the outside. In an embodiment, the camera 236 may obtain an image of an external environment and/or an external object through the opening.

In an embodiment, the fourth surface 222 of the second housing part 220 may further include at least one camera 234 and the display 235 visible through a portion of the fourth surface 222.

In an embodiment, the hinge structure 260 may be configured to pivotally connect the first bracket 270 forming the first housing part 210 and the second bracket 280 forming the second housing part 220.

In an embodiment, the electronic device 201 may be in one of a folded state, an unfolded state, or an intermediate state. The folded state may be a state in which the first surface 211 of the first housing part 210 and the third surface 221 of the second housing part 220 face each other. In the folded state, a direction in which the first surface 211 faces and a direction in which the third surface 221 faces may be opposite to each other. The unfolded state may be a state in which the first surface 211 of the first housing part 210 and the third surface 221 of the second housing part 220 are substantially continuous planes. In the unfolded state, a direction in which the first surface 211 faces and a direction in which the third surface 221 faces may be the same. The intermediate state may be a state between the unfolded state and the folded state. In the intermediate state, a direction in which the first surface 211 faces and a direction in which the third surface 221 faces may be different from each other.

In an embodiment, while the electronic device 201 is in the folded state, at least a portion of the hinge cover 265 surrounding the hinge structure 260 may be exposed through the first housing part 210 and the second housing part 220. In an embodiment, while the electronic device 201 is in the unfolded state, the hinge cover 265 may be covered by the first housing part 210 and the second housing part 220.

In an embodiment, the electronic device 201 may be folded based on the folding axis 237 passing through the hinge cover 265 or the hinge structure 260. For example, the hinge structure 260 in the hinge cover 265 may be disposed between the first housing part 210 and the second housing part 220 of the electronic device 201 to bend, curve, or fold the electronic device 201. For example, the first housing part 210 may be connected to the second housing part 220 through the hinge structure 260 disposed in the hinge cover 265 and may be rotated based on the folding axis 237.

In an embodiment, the first housing part 210 and the second housing part 220 of the electronic device 201 may be folded to face each other by rotating based on the folding axis 237. In an embodiment, the electronic device 201 may be folded so that the first housing part 210 and the second housing part 220 are stacked or overlap each other.

In an embodiment, the hinge structure 260 may include the hinge module and the hinge plates 266 and 267. The hinge module may include a hinge gear 262 or 263 that may pivot the first housing part 210 and the second housing part 220.

The first housing part 210 may include the first bracket 270, and the second housing part 220 may include the second bracket 280. The first bracket 270 may be partially surrounded by the first sidewall 213, and the second bracket 280 may be partially surrounded by the second sidewall 223. The first bracket 270 may be integrally formed with the first sidewall 213, and the second bracket 280 may be integrally formed with the second sidewall 223. According to an embodiment, the first bracket 270 may be formed separately from the first sidewall 213, and the second bracket 280 may be formed separately from the second sidewall 223. The first sidewall 213 and the second sidewall 223 may be formed of a metal material, a non-metal material, or a combination thereof. For example, the first sidewall 213 may include a conductive portion 218 and a non-conductive portion 219. The conductive portion 218 may be used as a radiator of an antenna.

A surface of the first bracket 270 may be coupled to the back plate 290, and another surface of the first bracket 270 may be coupled to the foldable display 230. A surface of the second bracket 280 may be coupled to the display 235, and another surface of the second bracket 280 may be coupled to the foldable display 230.

The printed circuit board 250 and a battery may be disposed in a space between a surface formed by the first bracket 270 and the second bracket 280 and a surface formed by the display 235 and the back plate 290. The printed circuit board 250 may be separated to be disposed on each of the first bracket 270 of the first housing part 210 and the second bracket 280 of the second housing part 220. Components for implementing various functions of the electronic device 201 may be disposed on the printed circuit board 250.

According to an embodiment, components for implementing an overall function of the electronic device 201 may be disposed on the first printed circuit board 251, and electronic components for implementing a portion of functions of the first printed circuit board 251 or components for driving a display panel disposed on the fourth surface 222 may be disposed on the second printed circuit board 252. The first printed circuit board 251 and the second printed circuit board 252 may be electrically connected by a flexible printed circuit board 240.

For example, a battery 255, which is a device for supplying power to at least one component of the electronic device 201, may include, for example, a non-rechargeable primary battery, a rechargeable secondary battery, or a fuel cell. At least a portion of the battery 255 may be disposed on substantially the same plane as the printed circuit board 250. A surface formed on substantially the same plane as the printed circuit board 250 and the battery 255 may be disposed on a surface (e.g., a surface facing the second surface 212 and the fourth surface 222 or a surface facing a display panel and the back plate 290) of the first bracket 270 and the second bracket 280. For example, the foldable display 230 may be disposed on the first surface 211 and the third surface 221, and the printed circuit board 250 and the battery 255 may be disposed on the second surface 212 and the fourth surface 222 facing a surface on which the foldable display 230 is disposed.

The antenna 285 may be disposed between the back plate 290 and the battery 255, in an embodiment. The antenna 285 may include, for example, a near field communication (NFC) antenna, a wireless charging antenna, and/or a magnetic secure transmission (MST) antenna. The antenna 285 may perform, for example, short-range communication with an external device or wirelessly transmit and receive power required for charging.

In FIGS. 2A, 2B and 2C, the electronic device 201 has been illustrated as including a plurality of foldable housing parts, but it is not limited to thereto. For example, the electronic device 201 may be a bar type electronic device.

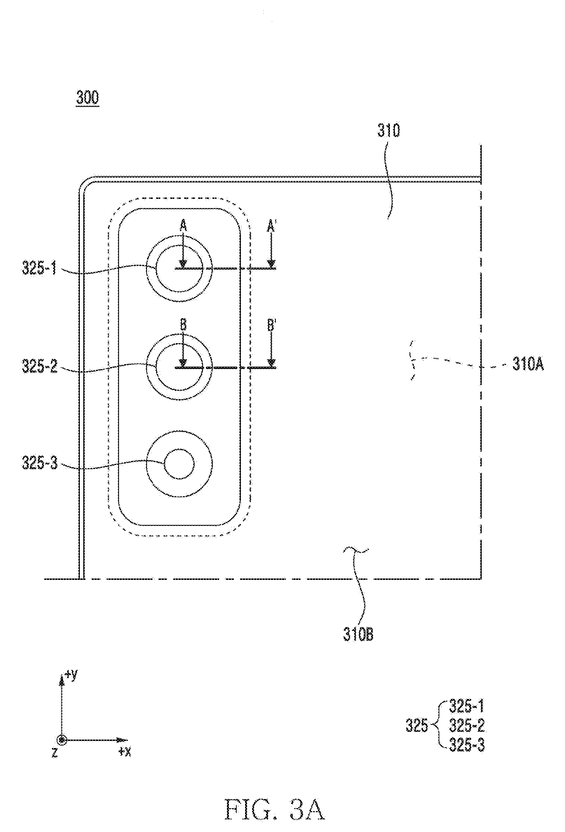

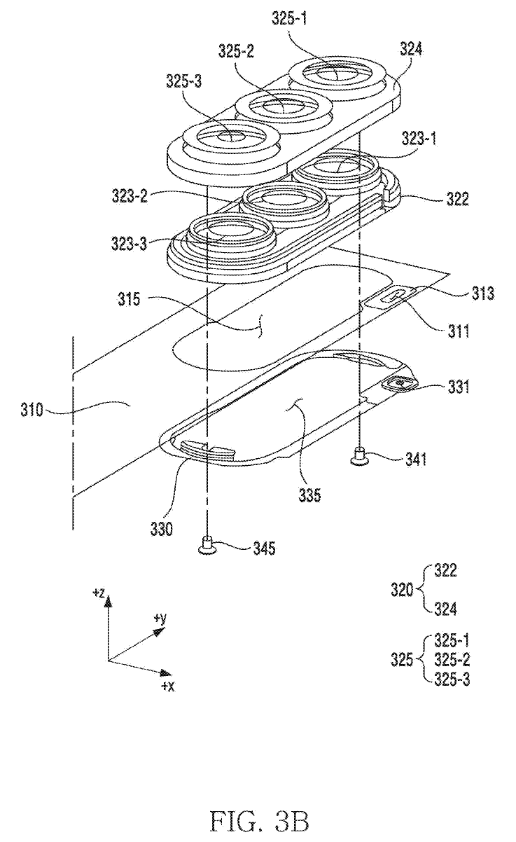

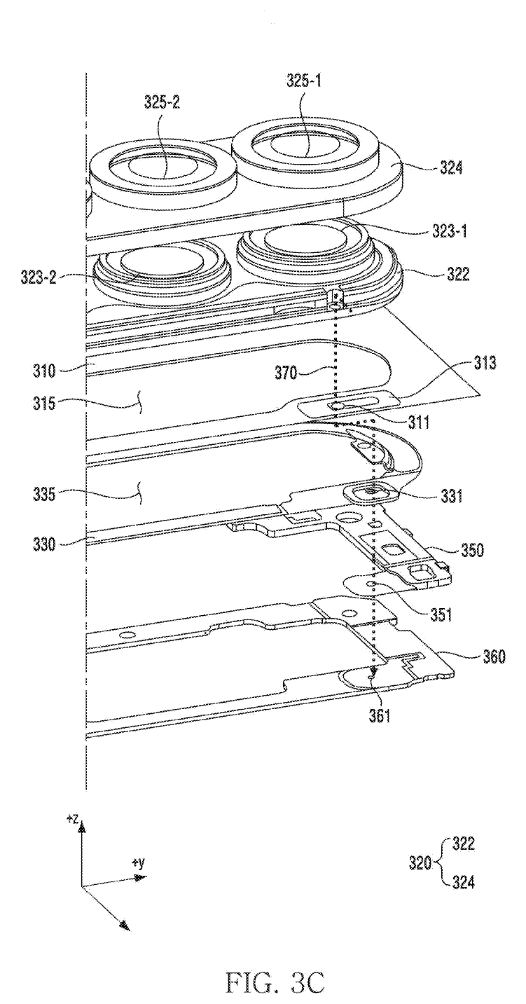

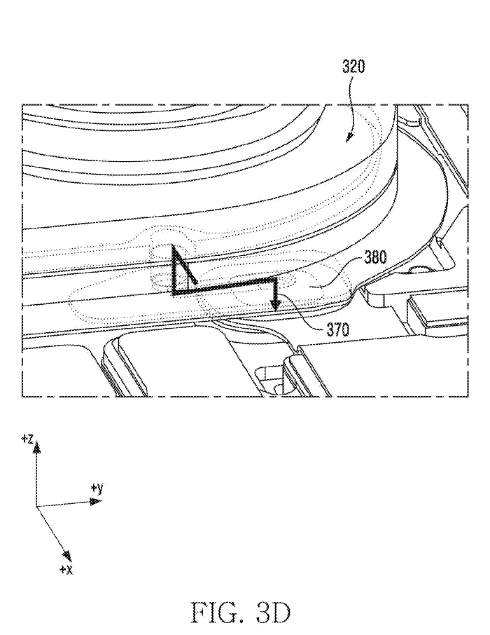

FIG. 3A is a diagram illustrating a portion of a rear side of a housing of an electronic device according to various embodiments. FIGS. 3B and 3C are partial exploded perspective views of an electronic device according to various embodiments. FIG. 3D is a partial perspective view of an electronic device according to various embodiments.

Referring to FIG. 3A, according to an embodiment, an electronic device 300 (e.g., the electronic device 201 of FIG. 2A) may include a housing (e.g., the first housing part 210 of FIG. 2A) including a rear cover 310 and a camera cover 320. Referring to FIGS. 3B and 3C, the electronic device 300 may include the rear cover 310, the camera cover 320, a bonding plate 330, a back plate 350, and a printed circuit board 360.

Referring back to FIG. 3A, the rear cover 310 may include a first surface 310A (or a front side (or a front side surface)) and a second surface 310B (or a rear side (or a rear side surface)) opposite the first surface 310A. The first surface 310A may face an inside of the electronic device 300, and the second surface 310B may face an outside of the electronic device 300. For example, the second surface 310B of the rear cover 310 may form (or define) at least a portion of a rear side (e.g., the second surface 212 of FIG. 2A) of the electronic device 300. The camera cover 320 may be referred to as camera decoration (or deco).

Referring to FIGS. 3B and 3C, the rear cover 310 may define an opening 315. In an embodiment, the opening 315 may penetrate through the rear cover 310. For example, the opening 315 may extend from the first surface 310A of the rear cover 310 to the second surface 310B.

Referring to FIGS. 3B and 3C, the rear cover 310 may define a first hole 311. In an embodiment, the first hole 311 may penetrate the rear cover 310. For example, the first hole 311 may extend from the first surface 310A of the rear cover 310 to the second surface 310B. For example, the first hole 311 may be spaced apart from the opening 315 (in a +x-axis direction).

For example, a member 313 may surround the first hole 311 on the rear cover 310 and may be interposed (positioned) (disposed) between the camera cover 320 and the rear cover 310. For example, the member 313 may include a material (e.g., sponge and/or rubber) configured to absorb and/or block a sound. For example, the member 313 may be an adhesive material (or a double-sided tape or a waterproof tape) that causes the camera cover 320 and the rear cover 310 to come into contact with each other.

In an embodiment, the camera cover 320 may be disposed to cover the opening 315 and the first hole 311 of the rear cover 310. In an embodiment, the camera cover 320 may be disposed on the rear cover 310. For example, the camera cover 320 may be disposed on the second surface 310B (or the rear side) of the rear cover 310. For example, the camera cover 320 may be disposed on the second surface 310B (or the rear side) of the rear cover 310 to cover the opening 315 and the first hole 311 of the rear cover 310. For example, the camera cover 320 may be attached to the second surface 310B (or the rear side) of the rear cover 310.

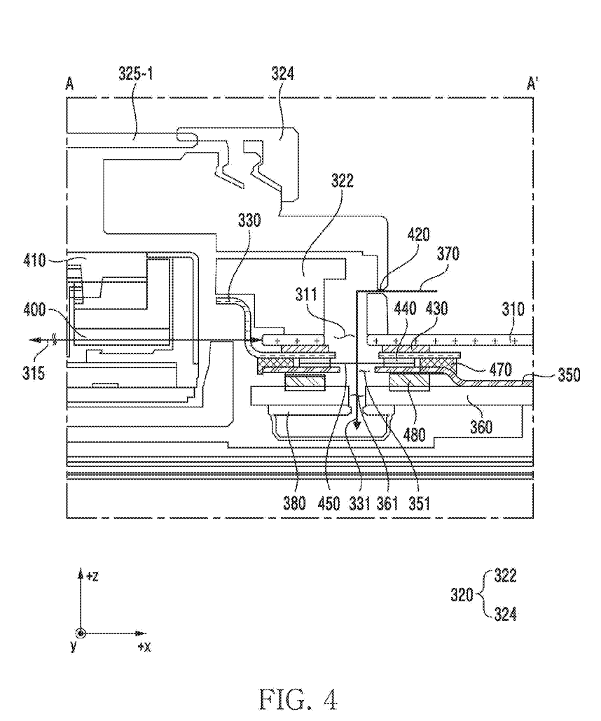

In an embodiment, the camera cover 320 may define a second hole (e.g., a hole 420 of FIG. 4) acoustically coupled to the first hole 311. In an embodiment, acoustic coupling of the first hole 311 and the second hole may refer to a sound signal 370 (or sound waves) passing through the second hole from the outside of the electronic device 300 being sequentially transmitted to the first hole 311 (or passing through the first hole 311). In an embodiment, a space in the camera cover 320 (or a space in which the sound signal 370 passing through the second hole (e.g., the hole 420 of FIG. 4) is transmitted (or guided) to the first hole 311) may be referred to as an acoustic pipeline.

In an embodiment, the camera cover 320 may include a first camera cover portion 322 and a second camera cover portion 324. In an embodiment, the second hole of the camera cover 320 may be defined (or formed) by a gap spaced between the first camera cover portion 322 and the second camera cover portion 324. For example, the second hole of the camera cover 320 may be covered by the second camera cover portion 324 when facing the rear of the electronic device 300.

In an embodiment, the first camera cover portion 322 may be disposed to cover the opening 315 and the first hole 311 of the rear cover 310. For example, the first camera cover portion 322 may be disposed on the rear cover 310 to cover the opening 315 and the first hole 311 of the rear cover 310. In an embodiment, the first camera cover portion 322 may be in contact with (or attached to) the rear cover 310 (e.g., by the adhesive material such as the double-sided tape and/or the waterproof tape).

For example, the first camera cover portion 322 may include one or more openings 323-1, 323-2, and 323-3 aligned with the one or more window portions 325, including 325-1, 325-2, and 325-3 of the second camera cover portion 324 of the camera cover 320. The one or more openings 323-1, 323-2, and 323-3 may be aligned in a direction (e.g., a -y axis direction or a +y axis direction).

In an embodiment, the first camera cover portion 322 may be formed by molding. In an embodiment, the first camera cover portion 322 may include a plastic material. In an embodiment, the first camera cover portion 322 may be formed of plastic. Areas surrounding each of the one or more openings 323-1, 323-2, and 323-3 may be formed to be substantially opaque. In an embodiment, hardness of the rear cover 310 may be higher than hardness of the first camera cover portion 322.

In an embodiment, the second camera cover portion 324 may be supported by the first camera cover portion 322 of the camera cover 320. In an embodiment, the second camera cover portion 324 may be in contact with (or attached to) (or disposed on) the first camera cover portion 322 on the first camera cover portion 322. For example, the second camera cover portion 324 may be disposed on the first camera cover portion 322 of the camera cover 320 to cover the one or more openings 323-1, 323-2, and 323-3 of the first camera cover portion 322. For example, the second camera cover portion 324 may be contact with (or attached to) the first camera cover portion 322 through the adhesive material (e.g., the double-sided tape, and/or the waterproof tape). In an embodiment, the first camera cover portion 322 may be covered by the second camera cover portion 324.

In an embodiment, the second camera cover portion 324 may include a metal material. In an embodiment, the second camera cover portion 324 may be formed of metal. For example without limitation, the second camera cover portion 324 may be formed of stainless steel. For example, hardness of the rear cover 310 may be lower than hardness of the second camera cover portion 324.

For example, the second camera cover portion 324 may include (or define) the one or more window portions 325-1, 325-2, and 325-3 for cameras. The one or more window portions 325-1, 325-2, and 325-3 may be formed to be substantially transparent. One or more cameras (e.g., a camera 400 of FIG. 4) may be configured to receive light through the one or more window portions 325-1, 325-2, and 325-3 of camera cover 320. Hereinafter, each of the one or more window portions 325-1, 325-2, and 325-3 may be referred to as a lens or a light transmission portion.

In an embodiment, one or more cameras (e.g., the at least one camera 234 of FIG. 2A) of the electronic device 300 may be disposed below the camera cover 320. For example, the camera cover 320 may include the one or more window portions 325-1, 325-2, 325-3 (or lenses, light transmitting portions) for the one or more cameras. In an embodiment, the one or more cameras may be arranged along a direction (e.g., the -y axis direction or the +y axis direction). As a non-limiting example, the one or more cameras may include a wide-angle camera, an ultra-wide-angle camera, and/or a telephoto camera. In an embodiment, each of the one or more cameras may be included in camera modules that are distinct from each other. Alternatively, the one or more cameras may be included in one camera module.

In an embodiment, the one or more window portions 325-1, 325-2, and 325-3 of the camera cover 320 may be aligned with respect to each of the one or more cameras. For example, the one or more window portions 325-1, 325-2, and 325-3 may be disposed on (e.g., in a +z axis direction) each of the one or more cameras. For example, the one or more window portions 325-1, 325-2, and 325-3 may be substantially centered on an optical axis of each of the one or more cameras.

According to an embodiment, the camera cover 320 may be integrally formed. For example, the camera cover 320 may be a camera cover in which the first camera cover portion 322 and the second camera cover portion 324 are integrally formed. In an embodiment, in a case that the first camera cover portion 322 and the second camera cover portion 324 are integrally formed, the camera cover 320 may be formed (of a plastic material) by molding. In an embodiment, in a case that the first camera cover portion 322 and the second camera cover portion 324 are integrally formed, hardness of the camera cover 320 may be lower than hardness of the rear cover 310.

Referring to FIG. 3B, in an embodiment, the bonding plate 330 may be disposed between the rear cover 310 and the back plate 350. For example, the bonding plate 330 may be disposed below (e.g., in a -z axis direction) the rear cover 310. For example, the bonding plate 330 may be disposed on the first surface 310A of the rear cover 310. For example, the bonding plate 330 may be attached to the first surface 310A of the rear cover 310 (e.g., through the adhesive material such as the double-sided tape and/or the waterproof tape). For example, the bonding plate 330 may face at least a portion of the first camera cover portion 322 through the rear cover 310. For example, the bonding plate 330 and the first camera cover portion 322 may face each other with the rear cover 310 interposed therebetween. According to an embodiment, the bonding plate 330 may be referred to as an inner deco plate (or an inner decoration plate) (or a fastening plate).

For example, the bonding plate 330 may include a hole 331 acoustically coupled to the first hole 311 of the rear cover 310 and an opening 335 substantially centered on the opening 315 of the rear cover 310. For example, a size (or a diameter) of the opening 335 of the bonding plate 330 may be larger than a size (or a diameter) of the opening 315 of the rear cover 310. For example, the hole 331 of the bonding plate 330 may be radially misaligned with respect to the first hole 311. For example, a center of the hole 331 of the bonding plate 330 may not be aligned with respect to a center of the first hole 311. For example, when the rear cover 310 is viewed from a rear side (or in a -z-axis direction) of the electronic device 300, the center of the hole 331 of the bonding plate 330 may be spaced apart from the center of the first hole 311 in a designated direction (e.g., a +y-axis direction) along a circumference of the opening 315 or 335. In an embodiment, the hole 331 of the bonding plate 330 may be acoustically coupled to the first hole 311. For example, acoustic coupling of the hole 331 of the bonding plate 330 and the first hole 311 may refer to the sound signal 370 (or sound waves) sequentially passing through the second hole and the first hole 311 from the outside of the electronic device 300 being transmitted to the hole 331 of the bonding plate 330 (or passing through the hole 331 of the bonding plate 330). For example, as the hole 331 of the bonding plate 330 is radially misaligned with respect to the first hole 311, the sound signal 370 passing through the first hole 311 may be guided along a direction 310 (e.g., the +y axis direction) designated by the rear cover and then may pass through the hole 331.

In an embodiment, bonding members 341 and 345 may be configured to fasten the camera cover 320 to the rear cover 310. For example, the bonding members 341 and 345 may be configured to fasten the camera cover 320 to the rear cover 310 by being fastened to the camera cover 320 by penetrating through the bonding plate 330 and the rear cover 310 below the bonding plate 330. In an embodiment, the bonding members 341 and 345 (or fastening members) may fasten the first camera cover 322 (or a molded portion) of the camera cover 320 to the rear cover 310 by being inserted through the first surface 310A (or the front side) of the rear cover 310.

In an embodiment, the bonding members 341 and 345 may be members (e.g., screws (or bolts) (or rivets)) for fastening between the camera cover 320 and the rear cover 310.

According to an embodiment, the bonding plate 330 and the bonding members 341 and 345 may be omitted. In a case that the bonding plate 330 and the bonding members 341 and 345 are omitted, the camera cover 320 may be attached to the rear cover 310 through a contact material.

In an embodiment, the back plate 350 may be disposed between the rear cover 310 (or the bonding plate 330) and the printed circuit board 360.

In an embodiment, the back plate 350 may define a hole 351 acoustically coupled to the first hole 311 of the rear cover 310 and the hole 331 of the bonding plate 330. For example, the hole 351 of the back plate 350 may be substantially aligned with respect to the hole 331 of the bonding plate 330. For example, when the bonding plate 330 is viewed from the rear side (or in the -z axis direction) of the electronic device 300, the hole 331 of the bonding plate 330 may overlap the hole 351 of the back plate 350. In an embodiment, the hole 351 of the back plate 350 may be acoustically coupled to the hole 331 of the bonding plate 330. For example, acoustic coupling of the hole 351 of the back plate 350 and the hole 331 of the bonding plate 330 may refer to a sound signal 370 (or sound waves) sequentially passing through the second hole, the first hole 311, and the hole 331 of the bonding plate 330 from an outside of the electronic device 300 being transmitted to the hole 351 of the back plate 350 (or passing through a hole 361 of the back plate 350).

In an embodiment, the printed circuit board 360 may be positioned below (or in the -z axis direction) the rear cover 310.

In an embodiment, the printed circuit board 360 may define a hole 361 aligned to transmit the sound signal 370 passing through the first hole 311 toward a microphone (e.g., a microphone 380 of FIG. 3D). For example, the hole 361 of the printed circuit board 360 may be substantially aligned with respect to the hole 351 of the back plate 350 and the hole 331 of the bonding plate 330. For example, the hole 361 of the printed circuit board 360 may be aligned in a designated direction (e.g., a -z axis direction) with respect to the hole 351 of the back plate 350 and the hole 331 of the bonding plate 330. For example, when the printed circuit board 360 is viewed from a rear side of the electronic device 300 (or in the -z axis direction), the hole 361 of the printed circuit board 360 may overlap the hole 351 of the back plate 350 and the hole 331 of the bonding plate 330. In an embodiment, the hole 361 of the printed circuit board 360 may be acoustically coupled to the hole 351 of the back plate 350. For example, acoustic coupling of the hole 361 of the printed circuit board 360 and the hole 351 of the back plate 350 may refer to the sound signal 370 (or sound waves) sequentially passing through the second hole and the first hole 311, the hole 331 of the bonding plate 330, and the hole 351 of the back plate 350 from the outside of the electronic device 300 being transmitted to the hole 361 of the printed circuit board 360 (or passing through the hole 361 of the printed circuit board 360). In an embodiment, the sound signal 370 (or the sound waves) transmitted to the hole 361 of the printed circuit board 360 (or passing through the hole 361 of the printed circuit board 360) may be transmitted to the microphone 380. In an embodiment, referring to FIG. 3D, the microphone 380 may receive the sound signal 370 (or the sound waves) from the outside of the electronic device 300.

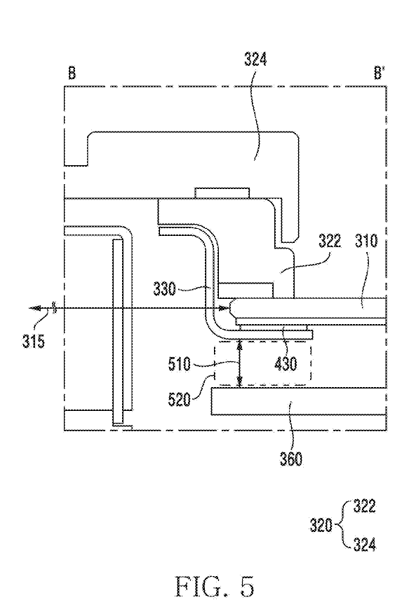

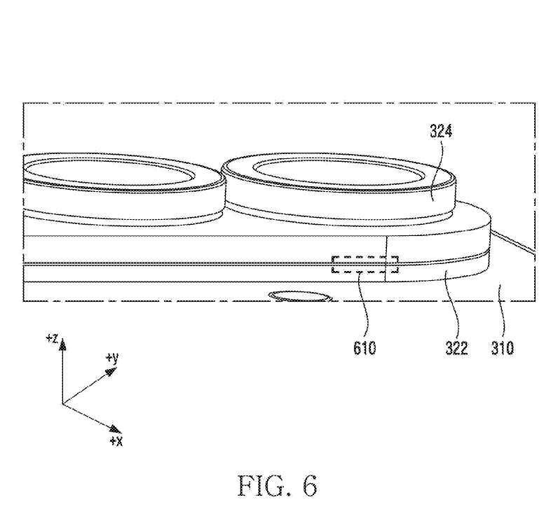

FIG. 4 is a cross-sectional view taken along line A-A′ of FIG. 3A according to various embodiments. FIG. 5 is a cross-sectional view taken along line B-B′ of FIG. 3A according to various embodiments. FIG. 6 is a partial perspective view of an electronic device according to various embodiments.

Referring to FIG. 4, a first camera 400 of one or more cameras may face a rear direction (e.g., a +z axis direction) of an electronic device 300. In an embodiment, the first camera 400 may be disposed in a housing such that a lens 410 is positioned within an opening 315 of a rear cover 310 when the lens 410 is viewed from a rear side of the housing. For example, a size (or a diameter) of the lens 410 may be larger than a size (or a diameter) of an opening 335 of the rear cover 310. In an embodiment, the lens 410 of the first camera 400 may be aligned with respect to a first window portion 325-1 (or a light transmitting portion) of a camera cover 320.

In an embodiment, the first camera 400 may receive light through the first window portion 325-1 and the lens 410. For example, the first camera 400 may be configured to obtain an image corresponding to the rear direction (e.g., the +z axis direction) of the electronic device 300 through the camera cover 320.

In an embodiment, a second hole 420 of the camera cover 320 may be formed at a position spaced apart from a rear side (or the second surface 310B of FIG. 3A) (or a surface in the +z axis direction) of the rear cover 310 by a designated height or more. In an embodiment, the second hole 420 of the camera cover 320 may be aligned to face a direction (e.g., a vertical direction) (e.g., the +z-axis direction) different from a direction (e.g., a +x-axis direction) of an image obtained by the first camera 400. For example, a second camera cover portion 324 of the camera cover 320 may be spaced apart from a first camera cover portion 322 of the camera cover 320 through a gap. The gap may be the second hole 420 acoustically connecting an outside of the electronic device 300 to an internal space of the electronic device 300. For example, the gap may be covered by the second camera cover portion 324 when the rear side of the electronic device 300 is viewed.

In an embodiment, the electronic device 300 may include a waterproof film 450 positioned (or disposed) (or interposed) between a back plate 350 and a bonding plate 330 and covering a hole 351 of the back plate 350 and/or a hole 331 of the bonding plate 330. The waterproof film 450 may be configured to reduce and/or prevent a foreign substance such as moisture and/or dust from entering the hole 351, and may be configured to pass through a sound signal (or sound waves).

For example, the waterproof film 450 may be disposed on a surface in an upper direction (e.g., the +z axis direction) of the back plate 350. For example, the waterproof film 450 may be disposed on a surface in a lower direction (e.g., a -z direction) of the bonding plate 330. For example, the waterproof film 450 may be attached to the bonding plate 330 through an adhesive material 440. In an adhesive material 332, a hole corresponding to the hole 331 of the bonding plate 330 may be formed.

In an embodiment, the electronic device 300 may include a printed circuit board 360 positioned below (e.g., in the -z axis direction) the back plate 350 and defining a hole 361. The printed circuit board 360 may include a first surface to face an acoustic member 480, the waterproof film 450, or the rear cover 310, the bonding plate 330, or the back plate 350. The printed circuit board 360 may include a second surface facing a microphone 380 and opposite to the first surface. For example, the first surface of the printed circuit board 360 may face the +z axis direction, and the second surface of the printed circuit board 360 may face the -z axis direction.

According to an embodiment, the electronic device 300 may include acoustic members 470 and 480 for sound insulation. The acoustic members 470 and 480 may include a material configured to absorb and/or block a sound, as a non-limiting example, such as a sponge and/or rubber. The acoustic members 470 and 480 may be referred to as sealing or sealing members.

In an embodiment, the acoustic member 470 may define a hole acoustically connecting the hole 331 to the hole 351. In an embodiment, the acoustic member 480 may define a hole acoustically connecting the hole 351 to the hole 361.

For example, the acoustic member 470 may be positioned (or disposed) (or interposed) between the rear cover 310 and the bonding plate 330. For example, the acoustic member 480 may be attached (e.g., through an adhesive material) to a surface of the back plate 350 facing the +z-axis direction (or a surface of the bonding plate 330 facing the -z-axis direction).

For example, the acoustic member 480 may be positioned (or disposed) (or interposed) between the rear cover 310 and the printed circuit board 360. For example, the acoustic member 480 may be attached (e.g., through an adhesive material) to a surface of the back plate 350 facing the -z-axis direction (or a surface of the printed circuit board 360 facing the +z-axis direction).

In an embodiment, the waterproof film 450 may overlap a portion of the acoustic member 470. For example, when viewed in a direction (e.g., the -z axis direction) perpendicular to the printed circuit board 360, the waterproof film 450 may overlap a portion of the acoustic member 470. For example, the waterproof film 450 may be aligned with a center of a hole of the acoustic member 470. A diameter of the waterproof film 450 may be larger than a diameter of a hole of the acoustic member 480.

According to an embodiment, the electronic device 300 may include a microphone 380 disposed on a surface facing a downward direction (the -z-axis direction) of the printed circuit board 360. For example, the microphone 380 may be mounted on the surface facing the downward direction (the -z axis direction) of the printed circuit board 360 to be aligned with the hole 361 of the printed circuit board 360. The microphone 380 may be configured to receive a sound signal (or sound waves) from the outside of the electronic device 300. For example, the microphone 380 may be configured to receive a sound signal from the outside sequentially passing through the holes 420, 311, 331, 351, and 361.

In a comparative example, the camera cover 320 may be positioned below the rear cover 310 and attached to the rear cover 310 below the rear cover 310. In this case, one or more cameras receive light through a portion of the opening 315 of the rear cover 310, and a sound signal for the microphone 380 may be obtained from the outside through the portion of the opening 315 (e.g., a gap formed by separation between the rear cover 310 and the camera cover 320). However, as the camera cover 320 is positioned below the rear cover 310 and attached to the rear cover 310 below the rear cover 310, it may be difficult to mount an electronic component in a portion of the printed circuit board 360 overlapping a portion to which the camera cover 320 and the rear cover 310 are attached. In addition, as the camera cover 320 is attached to the rear cover 310 below the rear cover 310, a thickness of the electronic device 300 may increase.

In addition, as the camera cover 320 is attached to the rear cover 310 below the rear cover 310, the portion of the opening 315 (e.g., the gap formed by the separation between the rear cover 310 and the camera cover 320) may be visible from the outside. As the portion of the opening 315 is visible from the outside, a user may mistake the portion of the opening 315 visible from the outside for a defect, and an aesthetic may be reduced. Additionally, the portion of the opening 315 used alone in which the sound signal for the microphone 380 is obtained from the outside may be blocked by an accessory (e.g., a mobile phone case) attached to the rear cover 310.

As described above, the electronic device 300 may have a structure in which a thickness of the electronic device 300 is reduced by disposing the camera cover 320 on the rear cover 310. Additionally, as the camera cover 320 is disposed on the rear cover 310, electronic components may be mounted in a portion overlapping a portion to which the camera cover 320 and the rear cover 310 are attached. For example, referring to FIG. 5, as the camera cover 320 is disposed on the rear cover 310, a height 510 between the printed circuit board 360 and the rear cover 310 (or the bonding plate 330) may be relatively increased. Accordingly, an electronic component may be mounted in a portion 520 overlapping a portion to which the camera cover 320 and the rear cover 310 are attached.

In addition, as described above, the first hole 311 may not be visible from the outside, as the electronic device 300 is disposed on the rear cover 310 such that the camera cover 320 covers the opening 315 and the first hole 311. In addition, for example, referring to FIG. 6, even if the user looks at a portion 610 where the second hole 420 of the camera cover 320 is disposed, it may be difficult for the second hole 420 to be visible from the outside as the second hole 420 of the camera cover 320 is covered by the second camera cover portion 324. In addition, even if an accessory (e.g., the mobile phone case) is attached to the rear cover 310, a sound signal passing through the second hole 420 may be less disturbed by the accessory (e.g., the mobile phone case) as the second hole 420 is formed at a position spaced apart from the rear cover 310 by a designated height.

A technical problem that may be addressed by the present disclosure is not limited to those described above, and any other technical problems not mentioned herein will be clearly understood by those having ordinary skill in the art to which the present disclosure belongs.

As described above, according to an example embodiment, an electronic device 300 may comprise a housing. The housing may include a rear cover 310 defining an opening 315 and a first hole 311. The electronic device 300 may comprise a camera 400. The camera 400 may be disposed in the housing such that a lens of the camera is positioned within the opening when the lens 410 of the camera 400 is viewed from a rear side of the housing. The electronic device 300 may comprise a camera cover 320 defining a second hole 420 acoustically coupled to the first hole 311 and disposed on the rear cover 310 to cover the opening and the first hole 311. The camera cover 320 may include a light transmitting portion 325-1 aligned with the lens 410 of the camera 400. The electronic device 300 may comprise a microphone 380 configured to receive sound waves from an outside of the electronic device 300 passing through the second hole 420 of the camera cover 320 and subsequently passing through the first hole 311 of the rear cover 310.

The camera cover 320 may include a molded portion 322 configured to contact a rear side of the rear cover 310. The molded portion 322 may be fastened to the rear cover 310 via a fastening member 341 or 345 inserted through a front side of the rear cover 310.

The camera cover 320 may comprise a first camera cover portion 322 disposed on the rear cover 310, and a second camera cover portion 324 disposed on the first camera cover portion 322. Hardness of the rear cover 310 may be higher than hardness of the first camera cover portion 322.

The hardness of the rear cover 310 may be lower than hardness of the second camera cover portion 324.

The first camera cover portion 322 may further comprise a plastic material. The second camera cover portion 324 may comprise a metal material.

The second hole 420 may be defined by a gap spaced between the first camera cover portion 322 and the second camera cover portion 324.

An adhesive material for adhering the second camera cover portion 324 on the first camera cover portion 322 may be further comprised.

The electronic device 300 may comprise a printed circuit board positioned below the rear cover, and defining a third hole aligned to transmit the sound signal passing through the first hole toward the microphone. The microphone 380 may be disposed below the printed circuit board 360.

The electronic device 300 may comprise an acoustic member 480 for soundproofing, interposed between the rear cover 310 and the printed circuit board 360, and defining a fourth hole connecting the first hole 311 of the rear cover 310 to the third hole of the printed circuit board 360.

The electronic device 300 may comprise a bonding plate 330 disposed between the rear cover 310 and the printed circuit board 360, and defining a fifth hole 331 connecting the first hole 311 of the rear cover 310 to the third hole of the printed circuit board 360, and a bonding member 341 or 345 fastened to the camera cover 320 by penetrating through the bonding plate 330 and the rear cover 310 below the bonding plate 330.

The electronic device 300 may comprise an adhesive material (or a waterproof tape 430, and/or a waterproof tape) interposed between the rear cover 310 and the bonding plate 330, and attaching the bonding plate 330 to the rear cover 310.

The fifth hole 331 may be radially misaligned with respect to the first hole 311, and aligned with respect to the third hole.

The connecting member 341 or 345 may be a screw.

The electronic device 300 may comprise a back plate 350 disposed between the rear cover 310 and the printed circuit board 360, and defining a sixth hole connecting the first hole 311 of the rear cover 310 to the third hole of the printed circuit board 360 and a waterproof film 450 disposed on the back plate 350, and covering the sixth hole of the back plate 350.

The electronic device 300 may comprise a bonding plate 330 disposed between the back plate 350 and the printed circuit board 360. The waterproof film 450 may be positioned between the back plate 350 and the bonding plate 330.

The sixth hole may be aligned with respect to the third hole.

The electronic device 300 may further comprise at least one electronic component disposed on the printed circuit board 360 between the printed circuit board 360 and a portion of the rear cover 310 above which the camera cover 320 is disposed.

A direction of the second hole 20 may be perpendicular to a direction of the light transmitting portion 325-1.

The electronic device 300 may further comprise an adhesive material for adhering the camera cover 320 to the rear cover 310.

The housing may include a first housing part including the rear cover 310 and the camera cover 320, and a second housing part rotatably coupled to the first housing part. The microphone 380 may be disposed within the first housing part.

The effects that may be obtained from the present disclosure are not limited to those described above, and any other effects not mentioned herein will be clearly understood by those having ordinary knowledge in the art to which the present disclosure belongs.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as "A or B," "at least one of A and B," "at least one of A or B," "A, B, or C," "at least one of A, B, and C," and "at least one of A, B, or C," may include any one of or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively", as "coupled with," or "connected with" another element (e.g., a second element), the element may be coupled with the other element directly (e.g., wiredly), wirelessly, or via a third element.

As used in connection with various embodiments of the disclosure, the term "module" may include a unit implemented in hardware, software, or firmware, or any combination thereof, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a housing including a rear cover defining an opening and a first hole,
a camera disposed in the housing such that a lens of the camera is positioned within the opening when the lens of the camera is viewed from a rear side of the housing,
a camera cover defining a second hole acoustically coupled to the first hole and disposed on the rear cover to cover the opening and the first hole, the camera cover including a light transmitting portion aligned with the lens of the camera, and
a microphone configured to receive sound waves from an outside of the electronic device passing through the second hole of the camera cover and subsequently passing through the first hole of the rear cover.

2. The electronic device of claim 1, wherein the camera cover includes a molded portion configured to contact a rear side of the rear cover,
wherein the molded portion is fastened to the rear cover via a fastening member comprising a fastener inserted through a front side of the rear cover.

3. The electronic device of claim 1,
wherein the camera cover comprises:
a first camera cover portion disposed on the rear cover, and
a second camera cover portion disposed on the first camera cover portion, and,
wherein hardness of the rear cover is greater than a hardness of the first camera cover portion.

4. The electronic device of claim 3,
wherein the hardness of the rear cover is less than a hardness of the second camera cover portion.

5. The electronic device of claim 3,
wherein the first camera cover portion comprises a plastic material, and
wherein the second camera cover portion comprises a metal material.

6. The electronic device of claim 3,
wherein the second hole is defined by a gap between the first camera cover portion and the second camera cover portion.

7. The electronic device of claim 3, further comprising:
an adhesive material configured to adhere the second camera cover portion on the first camera cover portion.

8. The electronic device of claim 1, comprising:
a printed circuit board positioned below the rear cover, and defining a third hole aligned and configured to transmit the sound waves passing through the first hole toward the microphone,
wherein the microphone is disposed below the printed circuit board.

9. The electronic device of claim 8, comprising:
an acoustic member comprising a sound blocking and/or sound absorbing material configured for soundproofing, interposed between the rear cover and the printed circuit board, and defining a fourth hole connecting the first hole of the rear cover to the third hole of the printed circuit board.

10. The electronic device of claim 8, comprising:
a bonding plate disposed between the rear cover and the printed circuit board, and defining a fifth hole connecting the first hole of the rear cover to the third hole of the printed circuit board, and
a bonding member comprising a fastener configured to fasten to the camera cover by penetrating through the bonding plate and the rear cover below the bonding plate.

11. The electronic device of claim 10, comprising:
a waterproof tape interposed between the rear cover and the bonding plate, and configured to attach the bonding plate to the rear cover.

12. The electronic device of claim 10,
wherein the fifth hole is:
radially misaligned with respect to the first hole, and
aligned with respect to the third hole.

13. The electronic device of claim 10,
wherein the bonding member includes a screw.

14. The electronic device of claim 8, comprising:
a back plate disposed between the rear cover and the printed circuit board, and defining a sixth hole connecting the first hole of the rear cover to the third hole of the printed circuit board, and
a waterproof film disposed on the back plate, and covering the sixth hole of the back plate.

15. The electronic device of claim 14, comprising:
a bonding plate disposed between the back plate and the printed circuit board, and
wherein the waterproof film is positioned between the back plate and the bonding plate.

16. The electronic device of claim 14,
wherein the sixth hole is aligned with respect to the third hole.

17. The electronic device of claim 1, further comprising:
at least one electronic component disposed on the printed circuit board between the printed circuit board and a portion of the rear cover above which the camera cover is disposed.

18. The electronic device of claim 1,
wherein a direction of the second hole is perpendicular to a direction of the light transmitting portion.

19. The electronic device of claim 1, further comprising:
an adhesive material configured to adhere the camera cover to the rear cover.

20. The electronic device of claim 1,
a housing including:
a first housing part including the rear cover and the camera cover, and
a second housing part rotatably coupled to the first housing part, and
wherein the microphone is disposed within the first housing part.
